(19) United States
(12) Patent Application Publication
(10) Pub. No.: US 2015/0137086 A1
(43) Pub. Date: May 21, 2015

(54) ORGANIC ELECTROLUMINESCENCE UNIT, METHOD OF MANUFACTURING THE SAME, AND ELECTRONIC APPARATUS

(71) Applicant: Sony Corporation, Tokyo (JP)

(72) Inventors: Ryo Yasumatsu, Kanagawa (JP); Makoto Ando, Tokyo (JP)

(21) Appl. No.: 14/402,261

(22) PCT Filed: May 10, 2013
(86) PCT No.: PCT/JP2013/063124

§ 371 Date: Nov. 19, 2014

(30) Foreign Application Priority Data
Jun. 1, 2012 (JP) 2012-126420

(51) Int. Cl. H01L 27/32; H01L 51/00; H01L 51/56

(52) U.S. Cl. CPC H01L 27/3246; H01L 51/56; H01L 51/0004; H01L 27/3218; H01L 27/3213; H01L 2251/558
USPC 257/40; 438/35

(57) ABSTRACT

An organic electroluminescence unit of the present disclosure includes: a plurality of light emitting devices arranged having a pitch from 10 micrometers to 60 micrometers both inclusive, and each including a first electrode, an organic layer, and a second electrode that are laminated in order from a substrate, the organic layer including at least a light emitting layer, and at least one layer in the organic layer being formed by a plate printing method; and a dividing wall provided between adjacent light emitting devices of the plurality of light emitting devices, in which a difference between a height, from the substrate, of the dividing wall and a height, from the substrate, of a surface to be printed by the plate printing method is from 0 micrometer to 1 micrometer both inclusive.

### TECHNICAL FIELD

The present disclosure relates to an organic electroluminescence unit that emits light utilizing organic electroluminescence (EL; Electro Luminescence) phenomenon, to a method of manufacturing the organic electroluminescence unit, and to an electronic apparatus that includes the organic electroluminescence unit.

### BACKGROUND ART

As development of information communication industry has been accelerated, a display device that has an advanced performance has been demanded. In such a circumstance, an organic EL device that has attracted attention as a next-generation display device has advantages that are not only a wide viewing angle and excellent contrast as a self-emitting-type display device, but also fast response time.

The organic EL device has a configuration in which a plurality of layers including a light emitting layer are laminated. These layers may be formed, for example, by a dry method such as a vacuum deposition method. Specifically, a general method may be a method in which a mask having an opening is sandwiched between a deposition source and a substrate, and a layer is patterned into a desired shape. In a display unit that uses such an organic EL device, when a size thereof is made larger or resolution thereof is made higher, the mask is curved and carrying thereof becomes complicated, which makes alignment difficult and decreases an opening rate. This causes an issue of decrease in device characteristics.

To address this, for example, Patent Literature 1 discloses a laser transfer method in which a transfer layer (an organic film) is formed on a donor film having concavities and convexities, and the organic film on the convex portion is transferred with the use of a laser. However, in this technique, the organic film is formed on the concavities and convexities, which causes an issue that it is difficult to maintain uniformity in thickness of the organic film.

Accordingly, Patent Literature 2 proposes a letterpress reverse offset printing method (hereinafter, simply referred to as “reverse offset printing method”) that uses a blanket. In the reverse printing method, ink that includes a light emitting material is applied onto the blanket, and an unnecessary region (a non-printing pattern) of an ink layer is then selectively removed with the use of an intaglio plate. By transferring, to a substrate to be printed, the blanket on which a printing pattern is thus formed, a light emitting layer is formed. In such a reverse printing method, the organic film is formed on a flat blanket, which makes it easy to form an organic film having a uniform thickness.

### CITATION LIST

### Patent Literature

### Patent Literature 1: Japanese Unexamined Patent Application Publication No. 2006-216562

### Patent Literature 2: Japanese Unexamined Patent Application Publication No. 2004-186111

### Patent Literature 3: Japanese Unexamined Patent Application Publication No. 2012-079621

### SUMMARY OF THE INVENTION

However, for example, in a display unit that has a dividing wall between devices as described in Patent Literature 3, when it is attempted to form an organic layer (for example, a light emitting layer) provided between the dividing walls by reverse printing, air intrudes between the light emitting layer and a substrate to be printed, and a printing pattern may not be transferred properly. For this reason, there has been an issue of decrease in light emitting characteristics.

Accordingly, it is desirable to provide an organic electroluminescence unit that suppresses intrusion of air at the time of printing with the use of a plate and has favorable light emitting characteristics, a method of manufacturing the organic electroluminescence unit, and an electronic apparatus.

An organic electroluminescence unit of an embodiment of the present technology includes: a plurality of light emitting devices arranged having a pitch from 10 micrometers to 60 micrometers both inclusive, and each including a first electrode, an organic layer, and a second electrode that are laminated in order from a substrate, the organic layer including at least a light emitting layer, and at least one layer in the organic layer being formed by a plate printing method; and a dividing wall provided between adjacent light emitting devices of the plurality of light emitting devices. In the organic electroluminescence unit, a difference between a height, from the substrate, of the dividing wall and a height, from the substrate, of a surface to be printed by the plate printing method is from 0 micrometer to 1 micrometer both inclusive.

A method of manufacturing an organic electroluminescence unit of an embodiment of the present technology includes the following (A) to (D), and a difference between a height of a dividing wall and a height of a surface to be printed by a plate printing method is caused to be from 0 micrometer to 1 micrometer both inclusive.

(A) forming a plurality of first electrodes having a pitch from 10 micrometers to 60 micrometers both inclusive
(B) forming a dividing wall between the plurality of first electrodes
(C) forming an organic layer on the plurality of first electrodes, the organic layer including at least a light emitting layer
(D) forming a second electrode on the organic layer

An electronic apparatus of an embodiment of the present technology includes the above-described organic electroluminescence unit.

In the organic electroluminescence unit of an embodiment of the present technology and in the method of manufacturing the organic electroluminescence unit, a difference in height between the surface to be printed by the plate printing method and the dividing wall provided between the light emitting devices in the light emitting devices that are arranged having the pitch from 10 micrometers to 60 micrometers both inclusive is caused to be 0 micrometer to 1 micrometer both inclusive. This suppresses intrusion of air between the surface to be printed and the organic layer when the organic layer including the light emitting layer in the light emitting device is formed by the plate printing method.

According to the organic electroluminescence unit of an embodiment of the present embodiment and the method of manufacturing the organic electroluminescence unit, the height of the dividing wall provided between the light emitting devices that are arranged having the pitch from 10 micrometers to 60 micrometers both inclusive is caused to have a difference, with the height of the surface to be printed by the plate printing method, from 0 micrometer to 1 micrometer both inclusive. This suppresses intrusion of air between the organic layer including the light emitting layer of the light emitting device and the surface to be printed at the time of printing, which allows the printing pattern to be transferred properly. This achieves favorable light emitting characteristics.

### BRIEF DESCRIPTION OF DRAWINGS

FIG. 1 is a cross-sectional view illustrating an example of a configuration of a display unit according to an embodiment of the present disclosure.

FIG. 2 is a schematic diagram for describing a configuration of a dividing wall and a first electrode in the display unit illustrated in FIG. 1.

FIG. 3 is a schematic diagram illustrating a circuit configuration example of a drive substrate in the display unit illustrated in FIG. 1.

FIG. 4 is an equivalent circuit diagram illustrating an example of a pixel circuit in the display unit illustrated in FIG. 1.

FIG. 5 is a cross-sectional view illustrating a configuration example of the drive substrate illustrated in FIG. 1.

FIG. 6A is a cross-sectional view for explaining a method of manufacturing the display unit illustrated in FIG. 1.

FIG. 6B is a cross-sectional view illustrating a step following FIG. 6A.

FIG. 6C is a cross-sectional view illustrating a step following FIG. 6B.

FIG. 6D is a cross-sectional view illustrating a step (a step of forming R and G light emitting layers) following FIG. 6C.

FIG. 6E is a cross-sectional view illustrating a step following FIG. 6D.

FIG. 6F is a cross-sectional view illustrating a step following FIG. 6D.

FIG. 6G is a cross-sectional view illustrating a step following FIG. 6F.

FIG. 7 is a schematic diagram for explaining a specific procedure of the step illustrated in FIG. 6D.

FIG. 8 is a schematic diagram illustrating a step following FIG. 7.

FIG. 9 is a schematic diagram illustrating a step following FIG. 8.

FIG. 10 is a schematic diagram illustrating a step following FIG. 9.

FIG. 11 is a cross-sectional view illustrating another example of the configuration of the display unit according to the embodiment of the present disclosure.

FIG. 12 is a cross-sectional view illustrating a configuration of a display unit according to Modification 1.

FIG. 13 is a perspective view illustrating a configuration of a smartphone that uses a display unit.

FIG. 14 is a perspective view illustrating a configuration of a television apparatus that uses a display unit.

FIG. 15 is a perspective view illustrating a configuration of a digital still camera that uses a display unit.

FIG. 16 is a perspective view illustrating an appearance of a personal computer that uses a display unit.

FIG. 17 is a perspective view illustrating an appearance of a video camcorder that uses a display unit.

FIG. 18 is a planar view illustrating a configuration of a mobile phone that uses a display unit.

### MODES FOR CARRYING OUT THE INVENTION

An embodiment of the present disclosure is described below in detail with reference to the drawings. Incidentally, the description is provided in the following order.
1. Embodiment (An example of a display unit that is configured of a red light emitting layer, a green light emitting layer, and a blue light emitting layer)
   1-1. Configurations of Surface to Be Printed and Dividing Wall
   1-2. Overall Configuration
   1-3. Manufacturing Method
2. Modification (An example of a display unit that is configured of a yellow light emitting layer and a blue light emitting layer)
3. Application Examples (Examples of electronic apparatuses)
4. Examples

### 1. Embodiment

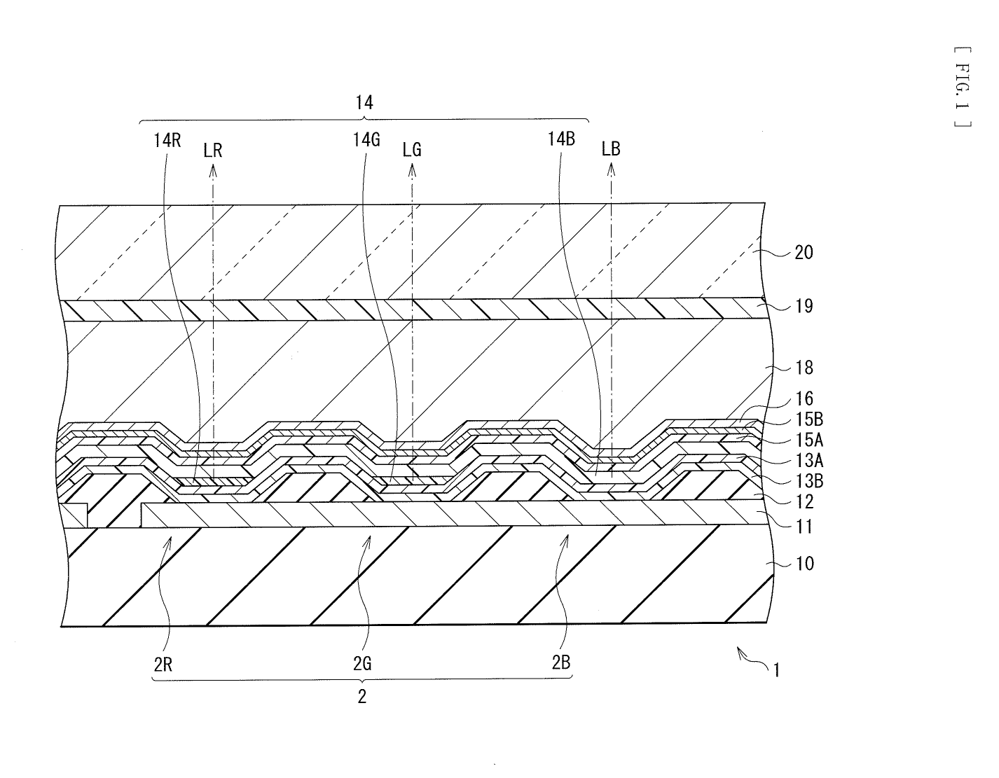

FIG. 1 illustrates a cross-sectional configuration of an organic electroluminescence unit (a display unit 1) according to an embodiment of the present disclosure. The display unit 1 may be used, for example, as an organic electroluminescence color display, etc. The display unit 1 may include, for example, a plurality of organic EL devices 2 (an organic EL device 2R (a red pixel) that generates red light, an organic EL device 2G (a green pixel) that generates green light, and an organic EL device 2B (a blue pixel) that generates blue light) that are regularly arranged on a drive substrate 10. These organic EL devices 2 are covered with a protection layer 18, and are sealed by a sealing substrate 20 with an adhesive layer 19 in between. In this display unit 1, a set of adjacent organic EL devices 2R, 2G, and 2B of the respective colors configure one pixel (pixel). This display unit 1 is a display unit of a top surface light emission type that emits light rays of LR, LG, and LB of three colors from a top surface of the sealing substrate 20. In the display unit 1 of the present embodiment, the organic EL device 2 includes a first electrode (a pixel electrode) 11, an organic layer including a light emitting layer 14, and a second electrode (a counter electrode) 16 that are laminated in order from the drive substrate 10. Here, the light emitting layer 14 is formed by a plate printing method. Further, dividing walls 12 are provided between the respective organic EL devices 2R, 2G, and 2B so as to surround the respective pixels.

[1-1. Configurations of Surface to be Printed and Dividing Wall]

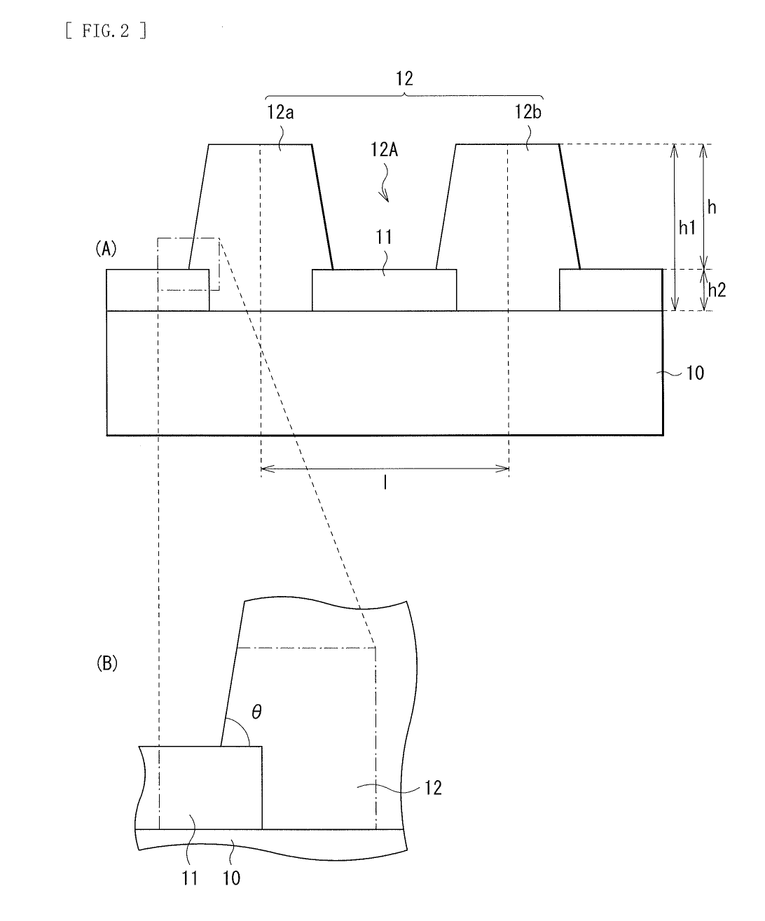

Part (A) of FIG. 2 schematically illustrates a configuration of the first electrode 11 and the dividing wall 12 in the display unit 1. The dividing wall 12 electrically insulates between the organic EL devices 2R, 2G, and 2B. Also, the dividing wall 12 partitions light emitting regions of the respective organic EL devices 2R, 2G, and 2B. The dividing wall 12 is provided so as to surround each of the pixels. An opening portion 12A is provided in each of the light emitting regions. In the opening portions 12A, the organic layers that include light emitting layers 14 that configure the corresponding organic EL devices 2R, 2G, and 2B are provided. In the organic EL device 2 in the present embodiment, the light emitting layers 14 (here, a red light emitting layer 14R and a green light emitting layer 14G) are formed by a plate printing method as described above. Examples of the plate printing method may include a reverse offset printing method and a gravure offset printing that use a blanket.

In the reverse offset printing method that uses a blanket (hereinafter, simply referred to as “reverse printing method”), a predetermined printing pattern is formed on a blanket, and the printing pattern is then transferred onto a substrate to be printed. Specifically, for example, when the blanket has a substantially rectangular shape, the printing pattern is transferred by gradually pressing the blanket onto the substrate to be printed with the use of a roll or the like from an arbitrary end to another end. Here, when printing is performed on a region (that is, a concave portion) in which a level difference, that is higher than the surface to be printed, is formed in the periphery thereof, the printing pattern is formed larger than a bottom surface of the concave portion. Specifically, for example, when printing is performed between the dividing walls 12 that have cross-sections on trapezoids illustrated in FIG. 2, the printing pattern is formed to extend to a top side of the dividing wall 12. When the printing is performed with the use of the blanket on which such a printing pattern is formed, air intrudes between the surface to be printed and the printing pattern, and the printing pattern may not be transferred properly, or gas may intrude therein to form an air bubble. In order to properly transfer the printing pattern in the reverse printing method, bend of a blanket base configuring the blanket and deformation of silicon rubber on which a coating film for printing is formed are important. Specifically, it may be considered that a transfer defect of the printing pattern occurs because, when pressing is performed from an arbitrary end (for example, a dividing wall 12a) to another end (for example, a dividing wall 12b) of the blanket, sufficient bend of the blanket and sufficient deformation do not occur between these dividing walls (in a region to be printed), and the blanket in contact with a top surface of the dividing wall 12a is brought into contact with a side surface or a top surface of the dividing wall 12b before being brought into close contact with a side surface of the dividing wall 12a, the first electrode 11, etc.

On the other hand, in the present embodiment, intrusion of gas is suppressed by defining a level difference between a surface to be printed (here, the first electrode 11) and side walls (here, the dividing walls 12) provided on both ends thereof. Specifically, when a pitch (a distance between center of one dividing wall 12a to center of another dividing wall 12b where the dividing walls 12a and 12b sandwich a light emitting region; I) is from 10 μm to 60 μm both inclusive, a difference (h) between a height (h1) of the dividing wall 12 and a height (h2) of the first electrode 11 may be preferably 1 μm or smaller. By causing the level difference to be 1 μm or smaller, the blanket on which the printing pattern is formed is bent sufficiently between the dividing walls, and may be brought into contact, for example, with from a top surface to a side surface on the dividing wall 12A side, from the first electrode 11 that is the surface to be printed to a side surface of the dividing wall 12b, and a top surface thereof in order. Thus, air in the opening portion 12A (air between the printing pattern and the first electrode 11) is removed in accordance with the contact of the blanket. This makes it possible to properly transfer, for example, the printing pattern of the light emitting layer 14 on the first electrode 11 with no air bubble mixed therein.

It is to be noted that the dividing wall 12 is provided so as to cover a peripheral portion of the first electrode 11. The dividing wall 12 has a height that is equivalent with that of the first electrode (h1=h2, h=0 μm) or higher (h1>h2). Also, although the details are described later, the dividing wall 12 is configured, for example, by forming a resin film by a spin coating method or the like, and then processing the formed resin film into a predetermined shape, for example, by photolithography or the like. Here, the shape of the cross-section of the dividing wall 12 may be a trapezoidal shape as illustrated in FIG. 1 or Part (A) of FIG. 2, or may be a rectangular shape. Specifically, an angle (θ) formed between the top surface of the first electrode 11 and the side surface of the dividing wall 12 illustrated in Part (B) in FIG. 2 may be from 0° to 90° both inclusive. It is to be noted that the top surface of the dividing wall 12 is described in a state horizontal to the drive substrate 10 in FIG. 1 and Part (A) of FIG. 2; however, this is not limitative. The top surface of the dividing wall 12 may have concavities and convexities or a curved surface as long as a difference between an uppermost portion of the dividing wall 12 and the top surface of the first substrate 11 is 1 μm or smaller. Moreover, here, the first electrode 11 serves as the surface to be printed. However, as in the display unit 1 illustrated in FIG. 1, for example, when a hole injection layer 13A and a hole transfer layer 13B are provided between the first electrode 11 and the light emitting layer 14, these layers 13A and 13B serve as the surface to be printed.

[1-2. Overall Configuration of Display Unit]

### (Drive Substrate 10)

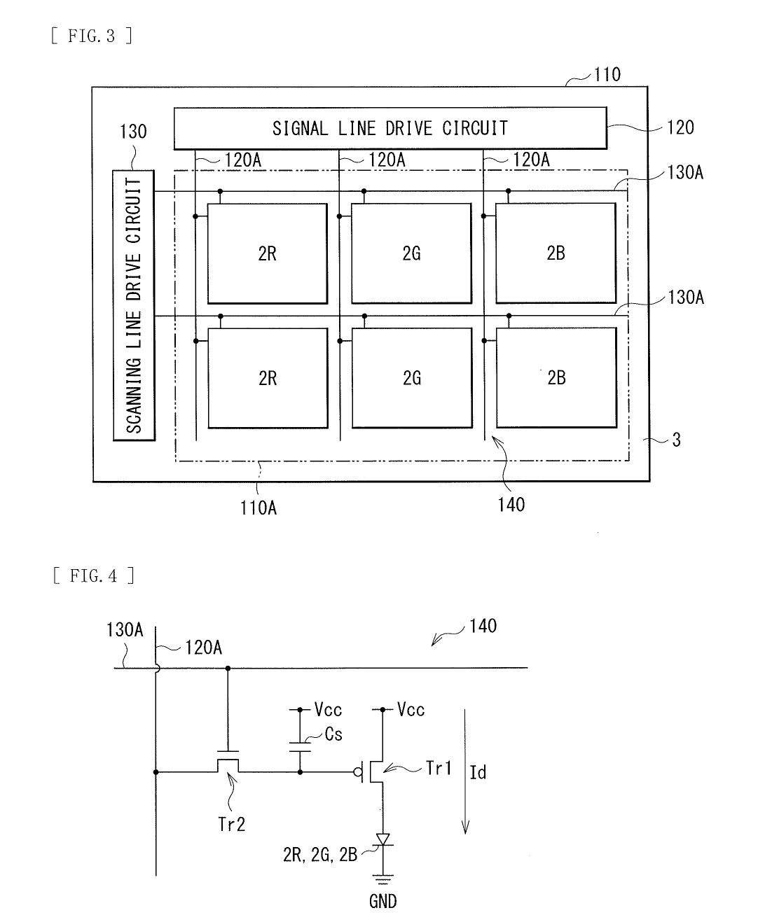

FIG. 3 illustrates a circuit configuration formed on the drive substrate 10 in the display unit 1, together with the above-described organic EL devices 2R, 2G, and 2B. In the drive substrate 10, for example, a display region 110A in which the plurality of organic EL devices 2R, 2G, and 2B are arranged in a matrix may be formed on a substrate 110, and a signal line drive circuit 120 and a scanning line drive circuit 130 that are drivers for displaying a video are provided so as to surround the display region 110A. A plurality of signal lines 120A that extend in a column direction are connected to the signal line drive circuit 120, and a plurality of scanning lines 130A that extend in a row direction are connected to the scanning line drive circuit 130. An intersection of each of the signal lines 120A and each of the scanning lines 130A corresponds to one of the organic EL devices 2R, 2G, and 2B. In a peripheral region of the display region 110A, a power line drive circuit which is not illustrated is provided other than these.

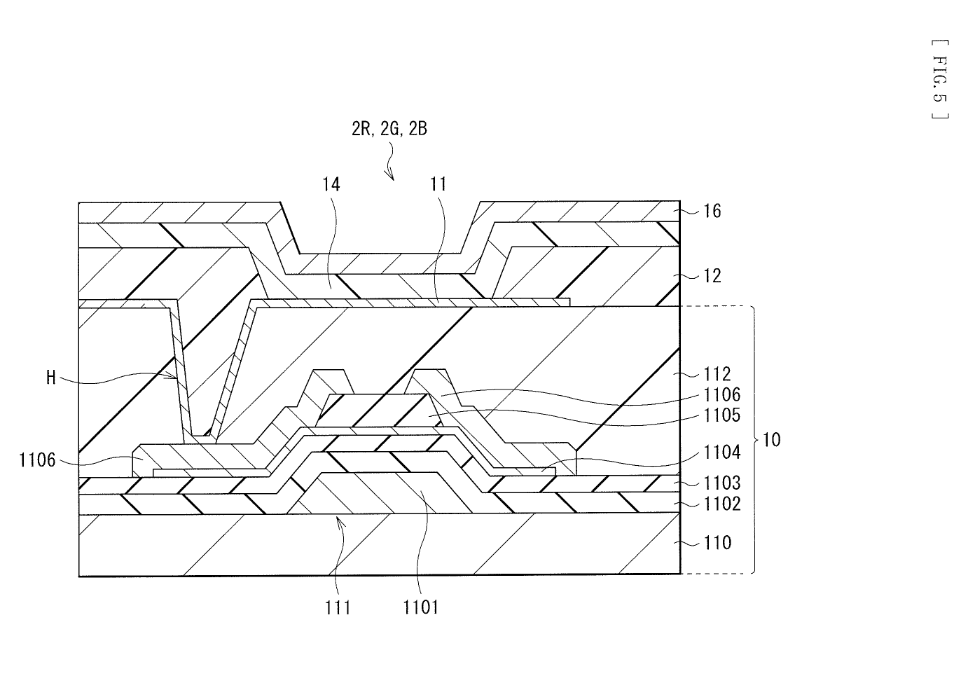

FIG. 4 illustrates an example of a pixel circuit 140 provided in the display region 110A. The pixel circuit 140 may include, for example, a drive transistor Tr1, a writing transistor Tr2 (corresponding to a TFT 111 which is described later), a capacitor (a retentive capacity) Cs between these transistors Tr1 and Tr2, and the organic EL device 2R, 2G, or 2B that is connected in series to the drive transistor Tr1 between a first power line (Vcc) and a second power line (GND). The drive transistor Tr1 and the writing transistor Tr2 are each configured of a general thin film transistor (TFT; Thin Film Transistor), and may be configured to have, for example, an inverted staggered structure (a so-called bottom-gate type) or a staggered structure (a top-gate type). Due to such a configuration, an image signal is supplied from the signal line drive circuit 120 to a source (or a drain) of the writing transistor Tr2 via the signal line 120A. A scanning signal is supplied from the scanning line drive circuit 130 to the gate of the writing transistor Tr2 via the scanning line 130A.

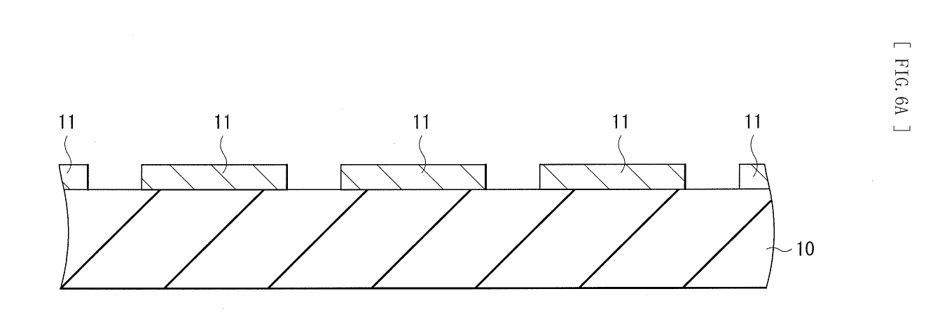

FIG. 5 illustrates a detailed cross-sectional configuration (a configuration of the TFT 111) of the drive substrate 10, together with a schematic configuration of the organic EL device 2R, 2G, or 2B. In the drive substrate 10, the TFT 111 corresponding to the above-described drive transistor Tr1 and the writing transistor Tr2 is formed. In the TFT 111, for example, a gate electrode 1101 is provided in a selective region on the substrate 110, and a semiconductor layer 1104 is formed on the gate electrode 1101 with gate insulating films 1102 and 1103 in between. A channel protection film 1105 is provided on a region (a region facing the gate electrode 1101) that serves as a channel of the semiconductor layer 1104. Each of a pair of source-drain electrodes 1106 is electrically connected to the semiconductor layer 1104. A planarization layer 112 is formed over an entire surface of the substrate 110 so as to cover such a TFT 111.

The substrate 110 may be formed, for example, of a glass substrate, or a plastic substrate. Alternatively, the substrate 110 may be that in which a surface of quartz, silicon, metal, or the like is subjected to an insulating process. Alternatively, the substrate 110 may be flexible or rigid.

The gate electrode 1101 has a role of controlling carrier density in the semiconductor layer 1104 by a gate voltage to be applied to the TFT 111. The gate electrode 1101 may be configured, for example, of a single-layer film made of one of Mo, Al, aluminum alloy, etc. or a laminated film made of two or more thereof. Examples of the aluminum alloy may include aluminum-neodymium alloy.

The gate insulating films 1102 and 1103 may be each configured, for example, of a single-layer film made of one of a silicon oxide film (SiOₓ), silicon nitride (SiNₓ), silicon oxynitride (SiON), aluminum oxide (Al₂O₂), etc., or a laminated film made of two or more thereof. Here, the gate insulating film 1102 may be configured, for example, of SiO₂, and the gate insulating film 1103 may be configured, for example, of Si₃N₄. A total thickness of the gate insulating films 1102 and 1103 may be, for example, from 200 nm to 300 nm.

The semiconductor layer 1104 may be configured, for example, of an oxide semiconductor that includes, as a main component, at least one oxide of indium (In), gallium (Ga), zinc (Zn), tin (Sn), Al, and Ti. The semiconductor layer 1104 forms a channel between the pair of source-drain electrodes 1106 by application of the gate voltage. The semiconductor layer 1104 may desirably have a thickness of a degree that does not cause degradation in ON current of the thin film transistor so that an influence of a negative charge described later is given on the channel. Specifically, the semiconductor layer 1104 may desirably have a thickness from 5 nm to 100 nm.

The channel protection film 1105 is formed on the semiconductor layer 1104, and prevents damage of the channel at the time of forming the source-drain electrodes 1106. The channel protection film 1105 may be configured, for example, of an insulating film that includes silicon (Si), oxygen (O₂), and fluorine (F), and may have a thickness, for example, from 10 nm to 300 nm.

The source-drain electrode 1106 serves as a source or a drain. The source-drain electrode 1106 may be configured, for example, of a single-layer film made of one of molybdenum (Mo), aluminum (Al), copper (Cu), titanium, ITO, titanium oxide (TiO), and the like, or may be a laminated film made of two or more thereof. For example, it may be desirable to use a tri-layer film configured of Mo, Al, and Mo laminated in order having thicknesses of 50 nm, 500 nm, and 50 nm, respectively. It may be also desirable to use metal or metal compound that has week bonding with oxygen, for example, metal compound that includes oxygen such as ITO or titanium oxide. Electric characteristics of the oxide semiconductor are stably retained thereby.

The planarization layer 112 may be configured, for example, of an organic material such as polyimide or novolac. The planarization layer 112 may have a thickness, for example, from 10 nm to 100 nm, and may preferably have a thickness of 50 nm or smaller. An anode electrode 12 of the organic EL device 2 is formed on the planarization layer 112.

It is to be noted that a contact hole H is provided in the planarization film 112. The source-drain electrode 1106 is electrically connected to each of the first electrodes 11 of the organic EL devices 2R, 2G, and 2B via the contact hole H. The first electrodes 11 are electrically separated for the respective pixels by the dividing walls 12. The organic layer 14 including the light emitting layers of the respective colors described later and the second electrode 16 are laminated on the first electrode 11. A detailed configuration of the organic EL devices 2R, 2G, and 2B is described later.

The protection layer 18 is for preventing intrusion of moisture into the organic EL devices 2R, 2G, and 2B. The protection layer 18 is configured of a material having low transmission characteristics and low water permeability, and may have a thickness, for example, from 2 μm to 3 μm. The protection layer 18 may be configured of any of an insulating material and a conductive material. As the insulating material, an inorganic amorphous insulating material, for example, amorphous silicon (α-Si), amorphous silicon carbide (α-SiC), amorphous silicon nitride (α-Si₁₋ₓNₓ), amorphous carbon (α-C), etc. may be mentioned. Such an inorganic amorphous insulating material does not configure a grain, and therefore has low water permeability, which achieves a favorable protection film.

The sealing substrate 20 seals the organic EL devices 2R, 2G, and 2B together with an adhesive layer 19. The sealing substrate 20 may be configured of a material such as glass transparent to light generated in the organic EL device 2. For example, a color filter and a black matrix (both are not illustrated) may be provided on the sealing substrate 20. In this case, light rays of the respective colors generated in the organic EL devices 2R, 2G, and 2B are extracted, and outside light reflected in the organic EL devices 2R, 2G, and 2B is absorbed, which improves contrast.

(Organic EL Devices 2R, 2G, and 2B)

Each of the organic EL devices 2R, 2G, and 2B may have, for example, a device structure of a top surface light emission type (a top emission type). However, each of the organic EL devices 2R, 2G, and 2B is not limited to such a configuration, and may be, for example, of a transmission type in which light is extracted from the substrate 110 side, i.e., of a bottom surface light emission type (a bottom emission type).

The organic EL device 2R is formed in the opening portion 12A in the dividing wall 12. The organic EL device 2R may be configured, for example, of the hole injection layer (HIL) 13B, the hole transfer layer (HTL) 13A, the red light emitting layer 14R, a blue light emitting layer 14B, an electron transfer layer (ETL) 15A, an electron injection layer (EIL) 15B, and the second electrode 16 that are laminated in order on the first electrode 11. This is similarly applicable to the organic EL device 2G. The organic EL device 2G may have, for example, a laminated structure in which the red light emitting layer 14R in the laminated structure of the organic EL device 2R is substituted by the green light emitting layer 14G. The organic EL device 2B may be configured, for example, of the hole injection layer 13B, the hole transfer layer 13A, the blue light emitting layer 14B, the electron transfer layer 15A, the electron injection layer 15B, and the second electrode 16 that are laminated in order on the first electrode 11. As described above, in the present embodiment, the red light emitting layer 14R and the green light emitting layer 14G are formed separately for each pixel, and the blue light emitting layer 14B is formed over the entire surface of the display region 110A and is shared by the respective pixels. Other than this, the hole injection layer 13B, the hole transfer layer 13A, the electron transfer layer 15A, and the electron injection layer 15B are provided to be shared by the respective pixels. Although detailed description is provided later, in the present embodiment, the red light emitting layer 14R and the green light emitting layer 14G are formed by a reverse printing method, and the blue light emitting layer 14B is formed by a vacuum deposition method.

The first electrode 11 may serve, for example, as an anode. When the display unit 1 is of a top surface light emission type, the first electrode 11 may be configured, for example, of a highly-reflective material such as aluminum, titanium, or chromium (Cr). It is to be noted that, when the display unit 1 is of a bottom surface light emission type, for example, a transparent conductive film made of a material such as ITO, IZO, or IGZO may be used.

As described above, the dividing wall 12 electrically insulates between the respective devices of the organic EL devices 2R, 2G, and 2B, and partitions the light emitting regions of the respective pixels. One of the organic EL devices 2R, 2G, and 2B is formed in each of the plurality of opening portions 12A formed by the dividing walls 12. The dividing wall 12 may be configured, for example, of an organic material such as polyimide, novolac resin, or acrylic resin. Alternatively, the dividing wall 12 may be configured of a lamination of the organic material and an inorganic material. Examples of the inorganic material may include SiO₂, SiO, SiC, and SiN.

The hole injection layer 13B is a buffer layer for improving efficiency of hole injection into the light emitting layers of the respective colors, and preventing leakage. The hole injection layer 13B may preferably have a thickness, for example, from 5 nm to 200 nm, and more preferably, from 8 nm to 150 nm. A material configuring the hole injection layer 13B may be appropriately selected in a relationship with the materials of adjacent layers such as the electrode. However, examples of the material configuring the hole injection layer 13B may include polyaniline, polythiophene, polypyrrole, polyphenylene vinylene, polythienylene vinylene, polyquinoline, polyquinoxaline, derivatives thereof, a conductive polymer such as a polymer including an aromatic amine structure in a main chain or a side chain, metal phthalocyanine (such as copper phthalocyanine), and carbon. Specific examples of the conductive polymer may include polydioxythiophene such as oligoaniline, oligoaniline, and poly(3,4-ethylenedioxythiophene) (PEDOT). Other than this, trade name Nafion (trademark) and trade name Liquion (trademark) available from H. C. Starck, trade name ELsource (trademark) available from Nissan Chemical Industries, Ltd., conductive polymer verazol available from Soken Chemical & Engineering Co., Ltd., etc. may be used.

The hole transfer layer 13A is for increasing efficiency of hole transfer into the light emitting layers of the respective colors. The hole transfer layer 13A may preferably have a thickness, for example, from 5 nm to 200 nm, and more preferably, from 8 nm to 150 nm, which may although depend on the overall configuration of the device. As a material configuring the hole transfer layer 13A, a polymer material that is soluble to an organic solvent, for example, polyvinyl carbazole, polyfluorene, polyaniline, polysilane, derivatives thereof, a polysiloxane derivative including aromatic amine in a side chain or a main chain, polythiophene, a derivative of polythiophene, polypyrrole, or 4,4′-bis(N-1-naphthyl-N-phenylamino)biphenyl (α-NPD) may be used.

The red light emitting layer 14R, the green light emitting layer 14G, and the blue light emitting layer 14B each cause recombination of an electron and a hole in response to application of an electric field, and thereby emit light. The light emitting layers of the respective colors may each preferably have a thickness from 10 nm to 200 nm, and more preferably, from 20 nm to 150 nm, which may although depend on the overall configuration of the device.

A material configuring each of the red light emitting layer 14R, the green light emitting layer 14G, and the blue light emitting layer 14B may be any material as long as the material is suitable for each of the light emitting color. Such a material may be a high molecular material (having a molecular weight, for example, of 5000 or more), or may be a low molecular material (having a molecular weight, for example, of 5000 or less). When using the low molecular material, for example, a mixed material including two or more of host materials and dopant materials may be used. When using the high molecular material, for example, the high molecular material may be used, for example, in a state of ink dissolved in an organic solvent. Alternatively, a mixed material including these low molecular material and high molecular material may be used.

As described above, in the present embodiment, the red light emitting layer 14R and the green light emitting layer 14G are formed by a reverse printing method that is a so-called wet method, and the blue light emitting layer 14B is formed by a vacuum deposition method that is a dry method. For this reason, the high molecular material is mainly used as the materials configuring the red light emitting layer 14R and the green light emitting layer 14G, and the low molecular material is mainly used for the blue light emitting layer 14B.

Examples of the high molecular material may include a polyfluorene-based high-molecular derivative, a (poly)p-phenylene vinylene derivative, a polyphenylene derivative, a polyvinylcarbazole derivative, a polythiophene derivative, a perylene-based pigment, a coumarin-based pigment, a rhodamine-based pigment, and mixtures in which a dopant material is mixed to these materials. Examples of the dopant material may include rubrene, perylene, 9,10-diphenylanthracene, tetraphenylbutadiene, nile red, coumarin 6, etc. may be mentioned. As the low molecular material, for example, benzine, styrylamine, triphenylamine, porphyrin, triphenylene, azatriphenylene, tetracianoquinodimethane, triazole, imidazole, oxadiazole, polyarylalkane, phenylenediamine, arylamine, oxazole, anthracene, fluorenone, hydrazone, stilbene, derivatives thereof, and a heterocyclic conjugated monomer or oligomer such as polysilane-based compounds, vinylcarbazole-based compounds, thiophene-based compounds, and aniline-based compounds. Further, the light emitting layer of each of the colors may include, as a guest material, a material having high light emission efficiency, for example, a low-molecular fluorescent material, phosphorescent pigment, metal complex, etc. other than the above-described materials.

The electron transfer layer 15A is for increasing efficiency of electron transfer to the light emitting layers of the respective colors. Examples of a material configuring the electron transfer layer 15A may include quinoline, perylene, phenanthroline, bisstyryl, pyrazine, triazole, oxazole, fullerene, oxadiazole, fluorenone, derivatives thereof, and metal complexes thereof. Specifically, tris(8-hydroxyquinoline)aluminum (abbreviated as Alq3), anthracene, naphthalene, phenanthrene, pyrene, anthracene, perylene, butadiene, coumarin, C60, acridine, stilbene, 1,10-phenanthroline, derivatives thereof, or metal complexes thereof may be mentioned. Other than this, an organic material that has a superior electron transfer performance may be preferably used. Specific examples thereof may include an arylpyridine derivative, and a benzoimidazole derivative. A total thickness of the electron transfer layer 15A and the electron injection layer 15B may be preferably, for example, from 5 nm to 200 nm, and more preferably, from 10 nm to 180 nm, which although depends on the overall configuration of the device.

The electron injection layer 15B is for increasing efficiency of electron injection into the light emitting layers of the respective colors. Examples of a material configuring the electron injection layer 15B may include alkali metal, alkaline-earth metal, rare-earth metal, oxides thereof, composite oxides thereof, fluorides thereof, and carbonates thereof.

The second electrode 16 may have, for example, a thickness of about 10 nm. In a case of the top surface light emission type, the second electrode 16 may be configured of a single-layer film of a conductive film material that has light transmission characteristics, or a laminated film including two or more thereof. Examples of such a conductive film material may include ITO, IZO, ZnO, InSnZnO, MgAg, and Ag. In a case of the bottom surface light emission type, for example, a high reflectance material such as aluminum, AlSiC, titanium, or chromium may be used.

[1-2. Manufacturing Method]

The display unit 1 as described above may be manufactured as follows, for example.

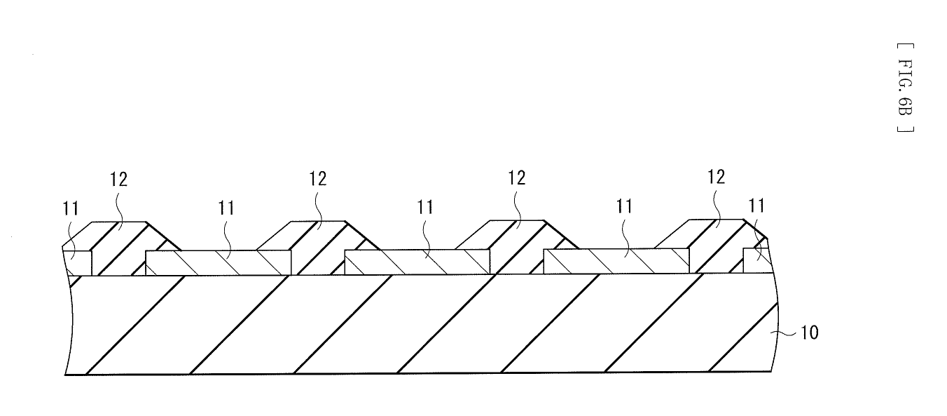

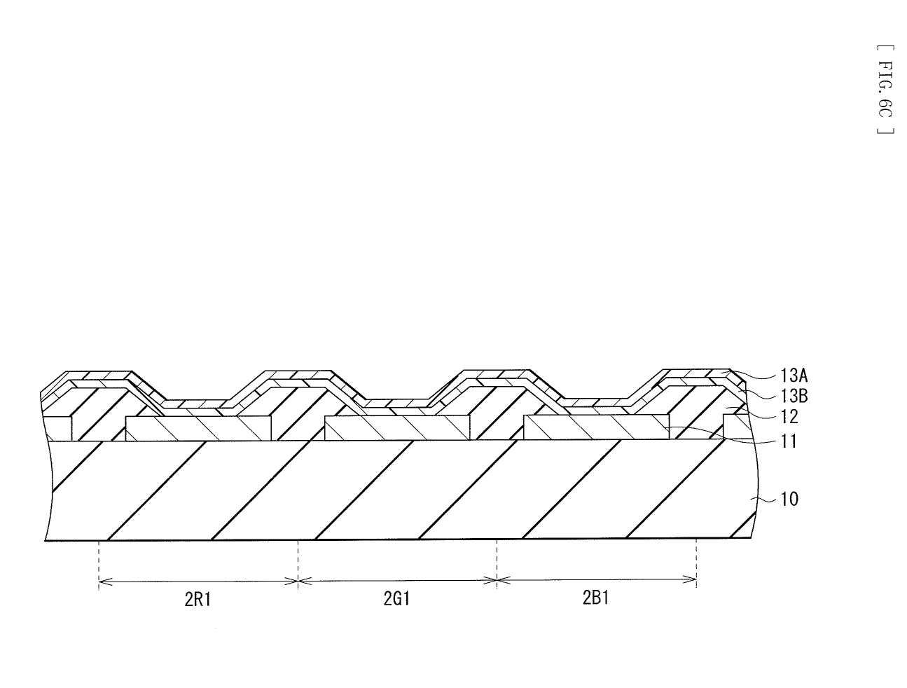

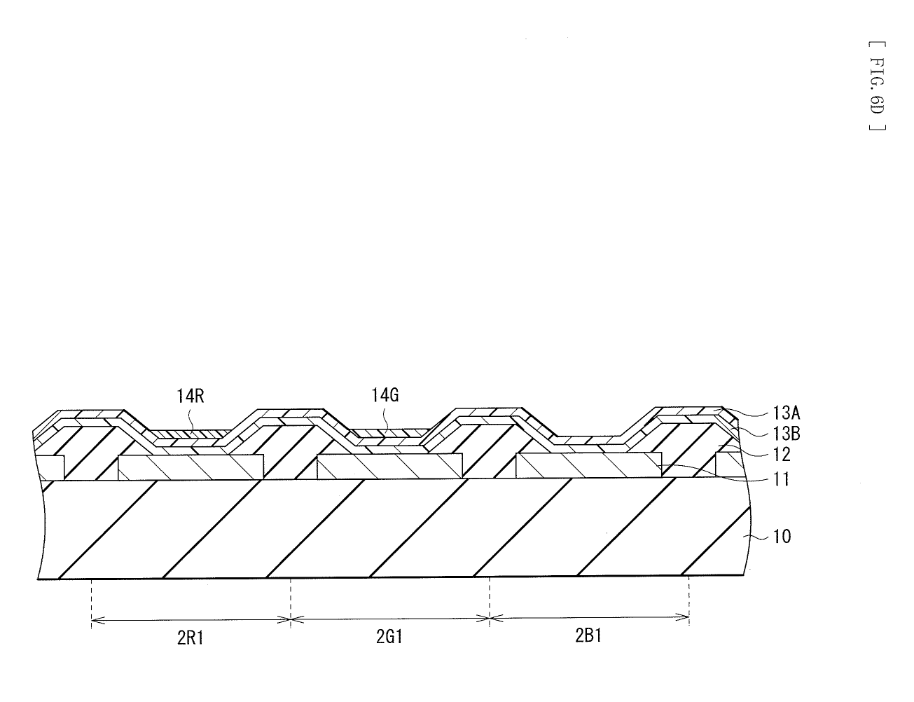

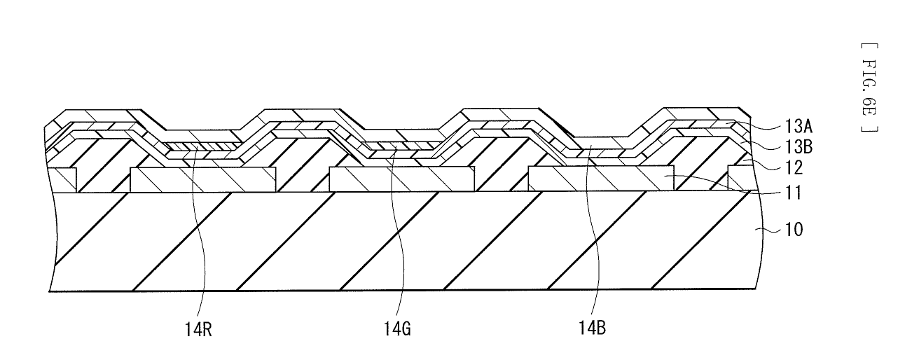

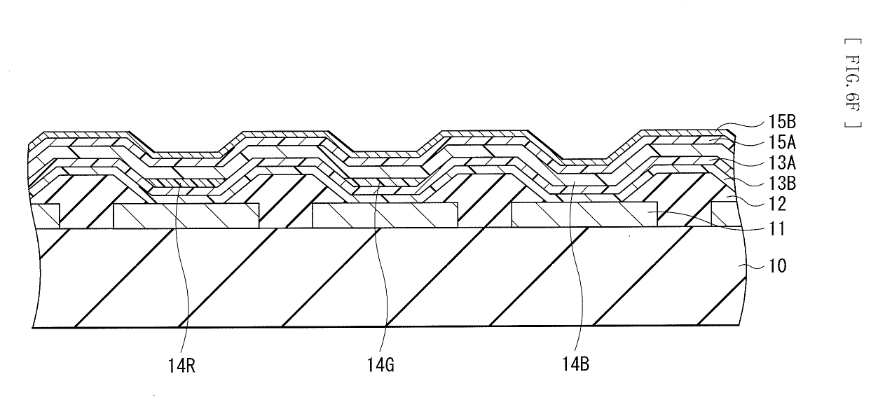

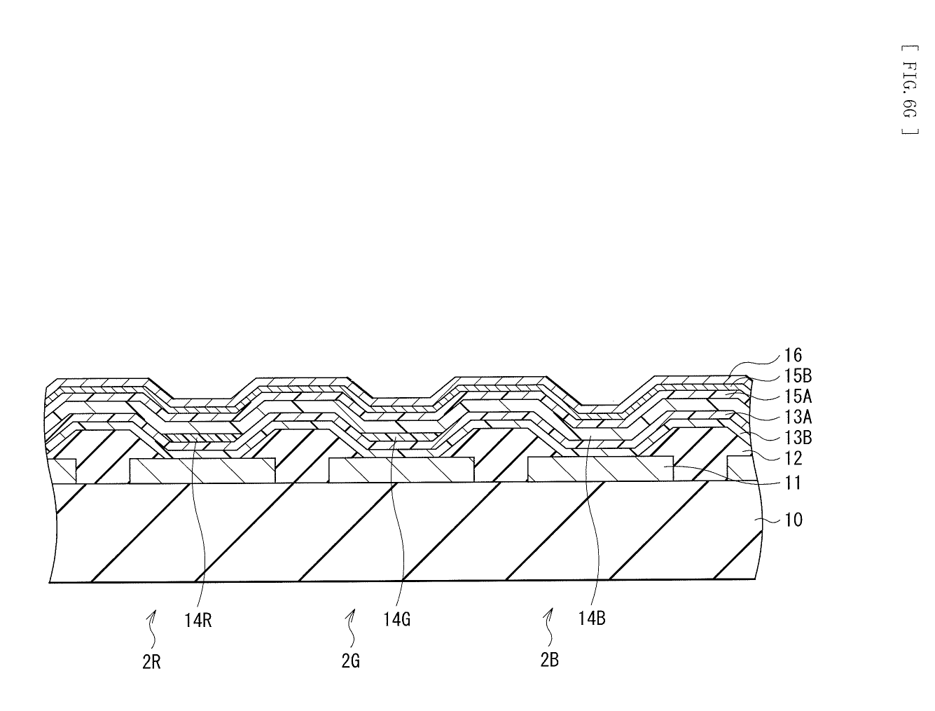

First, as illustrated in FIG. 6A, the first electrode 11 is formed on the drive substrate 10. At this time, the above-described electrode material may be deposited on the entire surface of the substrate, for example, by a vacuum deposition method or a sputtering method, and then, the deposited electrode material may be patterned, for example, by etching using a photolithography method. Further, the first electrode 11 is connected to the TFT 111 (in detail, to the source-drain electrode 1106) via the contact hole H in the planarization layer 112 formed in the drive substrate 10.

Subsequently, as illustrated in FIG. 6B, the dividing wall 12 is formed. Specifically, a resin film may be formed, using the above-described resin material, on the entire surface of the drive substrate 10, for example, by a spin coating method or the like. Thereafter, the opening portion 12A is provided in a portion corresponding to the first electrode 11, for example, by etching using a method such as a photolithography method. Thus, the dividing wall 12 is formed. After the opening portion 12A is formed, the dividing wall 12 may be reflowed as necessary. It is to be noted that, as a result of the etching of the resin film, an angle (θ) formed between the first electrode 11 and the side surface of the dividing wall 12 illustrated in Part (B) of FIG. 2 becomes about from 20° to 30°, for example, when polyimide is used. Moreover, the height of the dividing wall 12 and the angle (θ) are allowed to be adjusted by an application amount of the resin material configuring the dividing wall 12 and etching time.

Subsequently, as illustrated in FIG. 6C, the hole injection layer 13B and the hole transfer layer 13A may be deposited in order, for example, by a vacuum deposition method, so as to cover the first electrode 11 and the dividing wall 12. However, as a technique of depositing these hole injection layer 13B and hole transfer layer 13A, a direct application method such as a spin coating method, a slit coating method, or an inkjet method may be used other than the vacuum deposition method. Alternatively, a gravure offset method, a letterpress printing method, an intaglio plate reverse printing method, etc. may be used.

(Formation Step of G and R Light Emitting Layers)

Next, as illustrated in FIG. 6D, the red light emitting layer 14R is formed in a red pixel region 2R1, and the green light emitting layer 14G is formed in a green pixel region 2G1. At this time, as described below, the green light emitting layer 14G and the red light emitting layer 14R are formed in patterns in order by a reverse printing method using a blanket. Summary thereof is as follows.

1. Formation of first light emitting layer 14R
(1) Apply solution including a first light emitting material on the blanket.
(2) Form a printing pattern on the blanket with the use of an intaglio plate.
(3) Transfer the printing pattern on the blanket onto the drive substrate 10.
2. Formation of the second light emitting layer 14G
(1) Apply solution including a second light emitting material onto a blanket.
(2) Form a printing pattern on the blanket with the use of an intaglio plate.
(3) Transfer the printing pattern on the blanket onto the drive substrate 10.

1. Formation of First Light Emitting Layer

### (1) First Light Emitting Layer Application Step

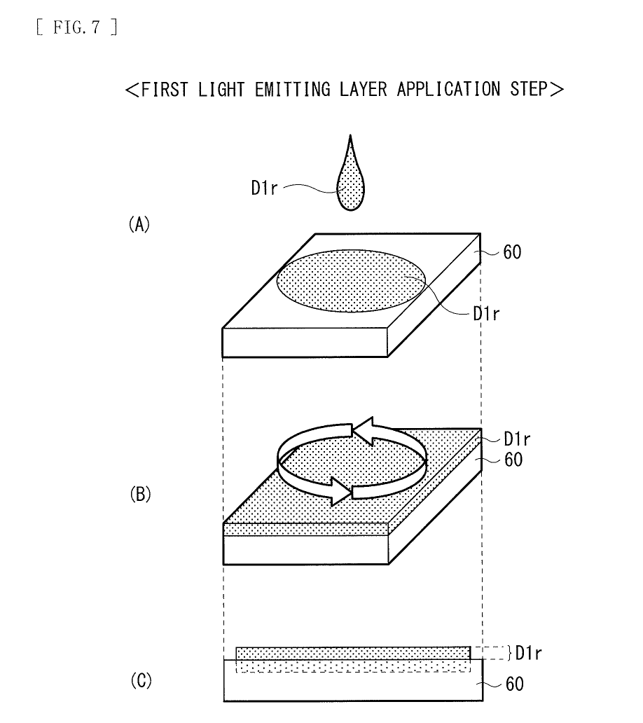

First, a blanket 60 is prepared that is used when a first light emitting layer (here, the red light emitting layer 14R) is transferred. Solution D1r that includes a red light emitting material is applied to be formed on the blanket 60. Specifically, as illustrated in Parts (A) and (B) of FIG. 7, the solution D1r is dripped onto the blanket 60, and the solution D1r is applied over the entire surface on the blanket 60, for example, by a direct application method such as a spin coating method or a slit coating method. Thus, a layer of the solution D1r including the red light emitting material is formed on the blanket 60 as illustrated in Part (C) of FIG. 7.

(2) Printing Pattern Formation Step

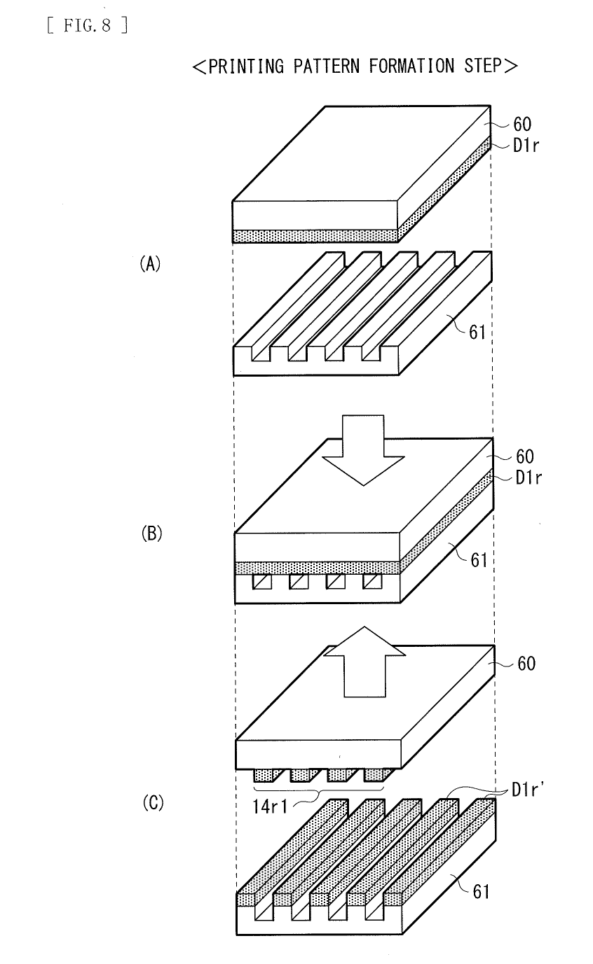

Subsequently, a printing pattern layer (a printing pattern layer 14g1) of the red light emitting layer 14R is formed on the blanket 60. Specifically, first, as illustrated in Part (A) of FIG. 8, an intaglio plate 61 that has concave portions in correspondence with the red pixel region 2G1 is brought to face the layer of the solution D1r on the blanket 60, and the layer of the solution D1r on the blanket 60 is pressed onto the intaglio plate 61 as illustrated in Part (B) of FIG. 8. Thereafter, as illustrated in Part (C) of FIG. 8, by peeling the blanket 60 off from the intaglio plate 61, an unnecessary portion (D1r′) of the layer of the solution D1r is transferred to the convex portion side of the intaglio plate 61 and is removed from the blanket 60. Thus, a printing pattern 14r1 of the red light emitting layer 14R corresponding to the red pixel region is formed on the blanket 60. It is to be noted that, although a shape of the pattern is illustrated as a linear pattern in the drawings, the shape of the pattern is not limited to a linear shape as long as the shape of the pattern is consistent with a TFT pixel arrangement.

(3) Transfer Step

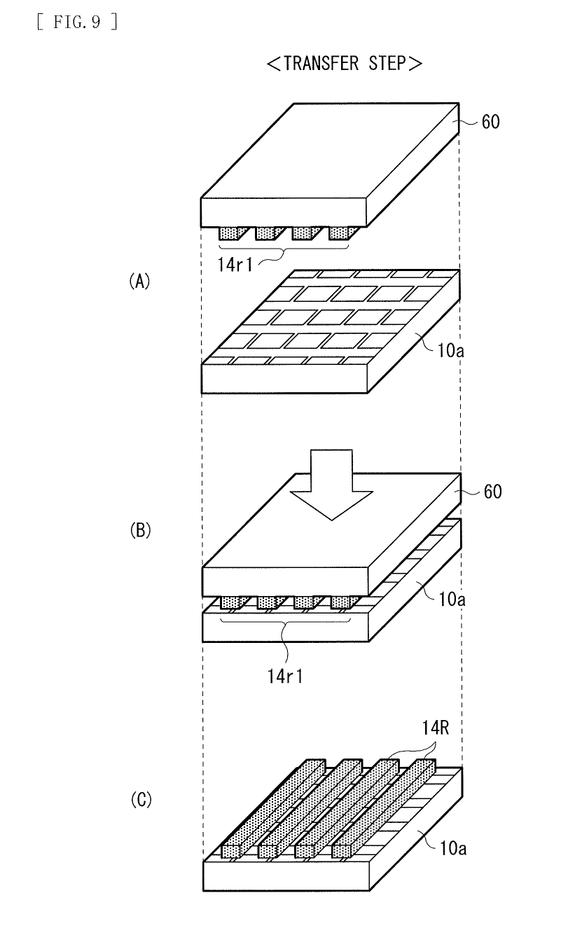

Subsequently, the printing pattern layer 14R1 of the red light emitting layer 14R on the blanket 60 is transferred onto the drive substrate 10 side. Specifically, first, as illustrated in Part (A) of FIG. 9, the drive substrate 10 (hereinafter, referred to as “drive substrate 10a” for the sake of convenience) on which the hole injection layer 13B and the hole transfer layer 13A have been already formed is arranged to face the blanket 60. Thereafter, the drive substrate 10a is aligned with the printing pattern 14r1, and a formation surface of the printing pattern layer 14r1 of the blanket 60 may be pressed onto the drive substrate 10a, for example, with the use of a transfer roller or the like, as illustrated in Part (B) of FIG. 9. Subsequently, by peeling the blanket 60 off from the drive substrate 10a, the red light emitting layer 14R is formed into a pattern on the drive substrate 10a (Part (C) of FIG. 9).

2. Formation of Second Light Emitting Layer

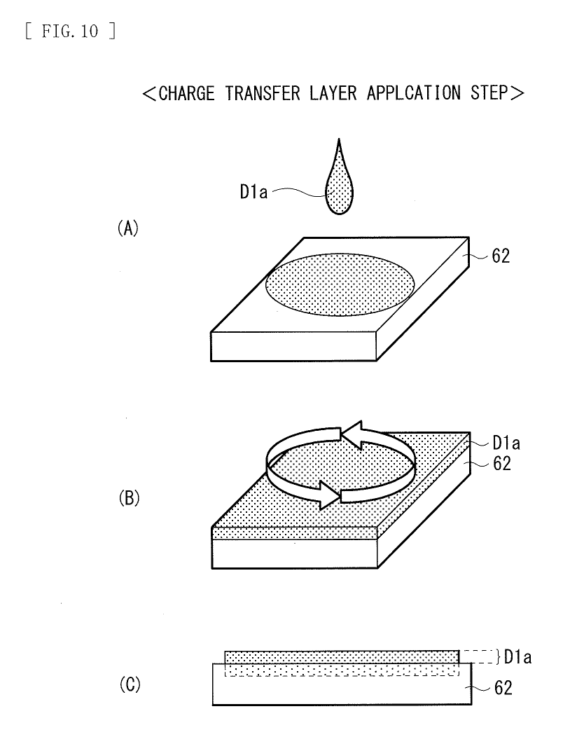

Subsequently, a blanket 62 that is used when a second light emitting layer (here, the green light emitting layer 14G) is prepared, and solution D1g including a green light emitting material is applied to be formed on the blanket 62. Specifically, as illustrated in Parts (A) and (B) of FIG. 10, the solution D1g is dripped onto the blanket 62, and the solution D1g is formed over the entire surface on the blanket 62, for example, by a direct application method such as a spin coating method or a slit coating method. Thus, a layer of the solution D1g including the green light emitting material is formed on the blanket 62 as illustrated in Part (C) of FIG. 10.

(2) Printing Pattern Formation Step and (3) Transfer Step

Subsequently, although not particularly illustrated, a printing pattern layer of the green light emitting layer is formed on the blanket 62 with the use of a predetermined intaglio plate, and the formed printing pattern layer is transferred onto the drive substrate 10 side, in a manner similar to that in the case of the above-described green light emitting layer 14R. Thus, the green light emitting layer 14G is formed on the drive substrate 10a.

Next, as illustrated in FIG. 6E, the blue light emitting layer 14B may be formed over the entire surface of the substrate, for example, by a vacuum deposition method. It is to be noted that the blue light emitting layer 14B is provided here as a common layer for the organic EL devices 2R, 2G, and 2B. However, this is not limitative. As in a display unit 2 illustrated in FIG. 11, the blue light emitting layer 14B may be formed by reverse printing as with the red light emitting layer 14R and the green light emitting layer 14G.

Subsequently, as illustrated in FIG. 6F, the electron transfer layer 15A and the electron injection layer 15B may be formed on the blue light emitting layer 14B, for example, by a vacuum deposition method. Thereafter, as illustrated in FIG. 6G, the second electrode 16 may be formed on the electron injection layer 15B, for example, by a vacuum deposition method, a CVD method, or a sputtering method. Thus, the organic EL devices 2R, 2G, and 2B are formed on the drive substrate 10.

Lastly, the protection layer 18 is formed so as to cover the organic EL devices 2R, 2G, and 2B on the drive substrate 10, and then the sealing substrate 20 is attached thereto with the adhesive layer 19 in between. Thus, the display unit 1 illustrated in FIG. 1 is completed.

[Functions and Effects]

In the display unit 1 of the present embodiment, the scanning signal is supplied from the scanning line drive circuit 130 to each of the pixels via the gate electrode of the writing transistor Tr2, and the image signal is retained in the retentive capacity Cs from the signal line drive circuit 120 via the writing transistor Tr2. Thus, a drive current Id is injected into the organic EL device 2, and a hole recombines with an electron, which causes light emission. This light may pass through the second electrode 16 and the sealing substrate 20, and may be extracted to the above of the display unit 1, for example, in the case of the top surface light emission type.

In such a display unit, in the manufacturing process, for example, when the light emitting layers (the red light emitting layer 14R and the green light emitting layer 14G) are formed by a reverse printing method with the use of a blanket in the light emitting region partitioned by the dividing wall as described above, gas may intrude between the surface to be printed and the printing pattern formed on the blanket due to the level difference between the dividing wall and the surface to be printed, which may cause the printing pattern not to be transferred properly or may cause a gas bubble to be formed.

On the other hand, in the present embodiment, the level difference between the surface to be printed (for example, the first electrode 11) and the dividing wall 12 is caused to be 1 μm or smaller. This causes the blanket on which the printing pattern is formed to be brought in contact, in the transfer step, for example, with from the top surface to the side surface of the dividing wall 12A side, from the first electrode 11 serving as the surface to be printed to the side surface and the top surface of the dividing wall 12b in order. In other words, air in the opening portion 12A (air between the printing pattern and the first electrode 11) is gradually removed from a direction of pressing of the surface to be printed and the blanket. This suppresses intrusion of air (remaining of an air bubble) between the surface to be printed and the printing pattern. Specifically, this suppresses occurrence of transfer defects such as wrinkle in the printing pattern, tear of the printing pattern resulting from break of the intruded air, and failing in transfer of the printing pattern onto the first electrode. Consequently, the printing pattern is allowed to be transferred properly, which makes it possible to provide a display unit exhibiting favorable light emitting characteristics.

Next, a modification according to the above-described embodiment is described. A component similar to that in the above-described embodiment is designated with the same numerals, and description thereof is omitted where appropriate.

### 2. Modification

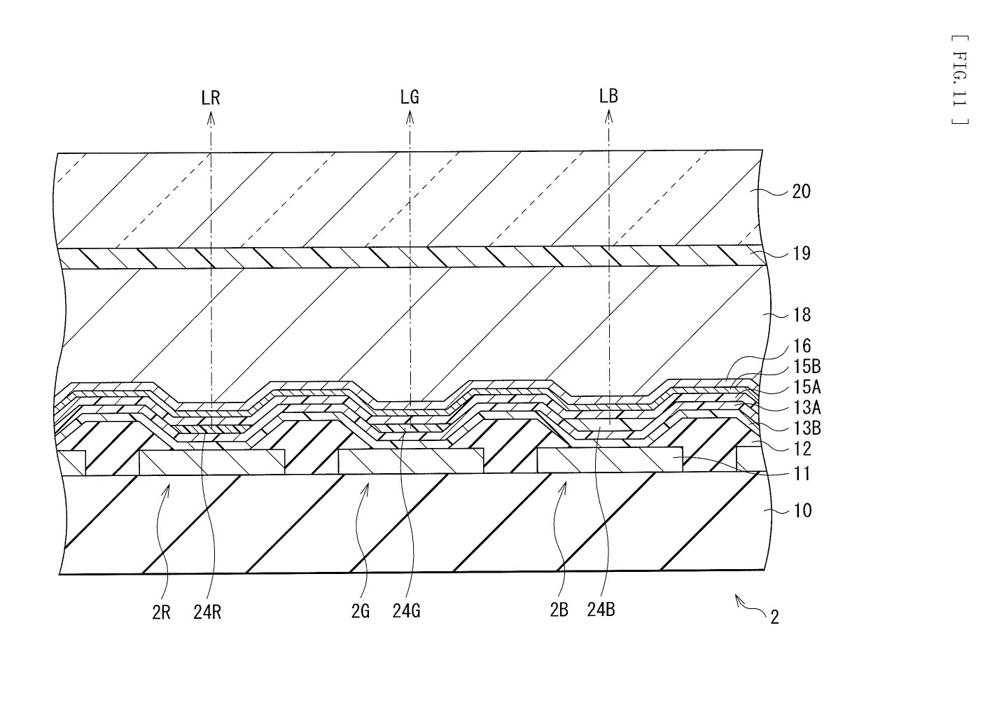

FIG. 12 illustrates a cross-sectional configuration of a display unit 3 according to Modification 1. In the above-described embodiment and the like, the red light emitting layer 14R and the green light emitting layer 14G are mentioned as examples of the light emitting layer formed into a pattern by reverse printing with the use of a blanket. However, the light emitting layer of other color may be used. For example, as in the present modification, a configuration may be adopted in which a yellow light emitting layer 34Y may be formed over two pixels of the organic EL devices 2R and 2G, and the blue light emitting layer 34B is formed to cover the yellow light emitting layer 34Y. In this case, white light is generated by color mixture of yellow and blue in the organic EL devices 2R and 2G. Therefore, a color filter layer (not illustrated) is provided on the sealing substrate 20 side, and red light and green light are each extracted with the use of the color filter layer. The color filter layer includes a red filter, a green filter, and a blue filter that face the organic EL devices 2R, 2G, and 2B, respectively. The red filter, the green filter, and the blue filter selectively allow red light, green light, and blue light to pass therethrough, respectively.

### 3. Application Examples

The display units 1 to 3 including the organic EL devices 2R, 2G, and 2B described in the above embodiment and Modification 1 may be mounted on an electronic apparatus in any field that performs image (or video) display as described below, for example.

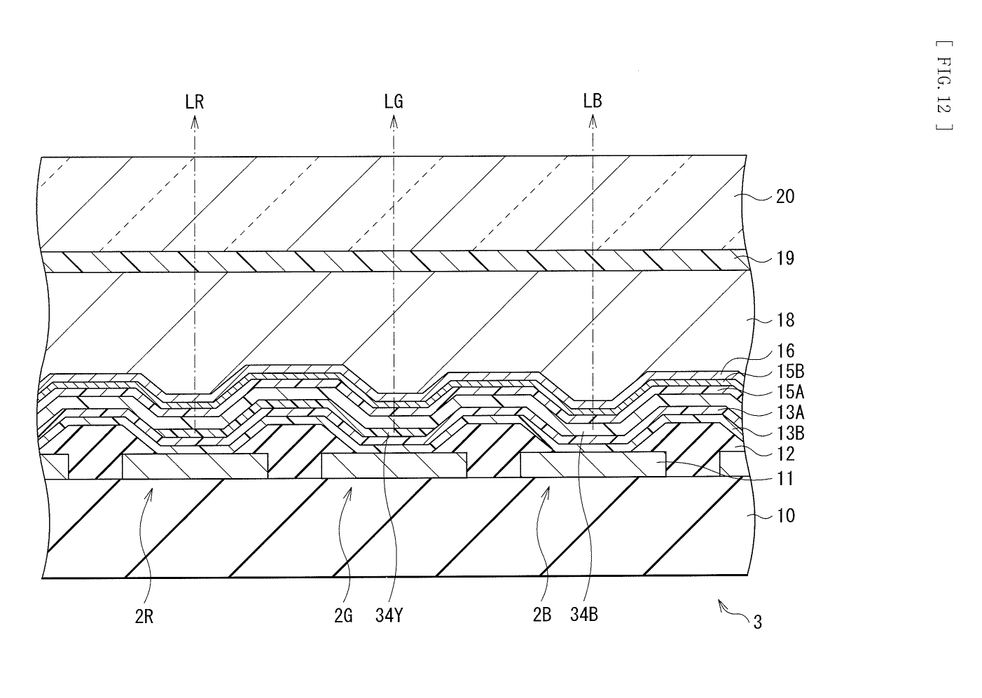

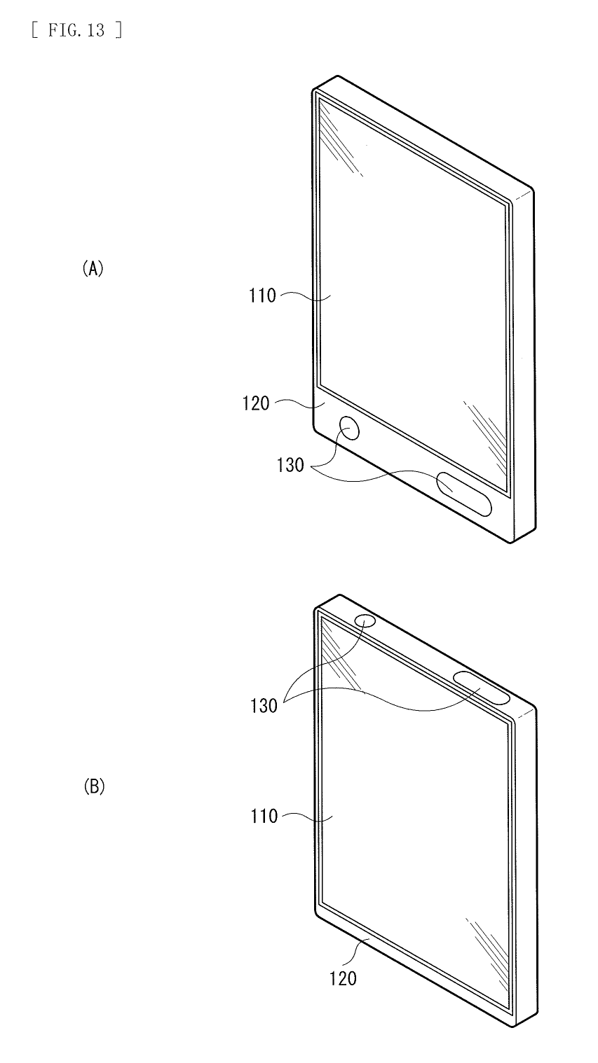

FIG. 13 illustrates an appearance of a smartphone. The smartphone may include, for example, a display section 110 (the display unit 1), a non-display section (a housing) 120, and an operation section 130. The operation section 130 may be provided on a front surface of the non-display section 120 as illustrated in Part (A), or may be provided on a top surface thereof as illustrated in Part (B).

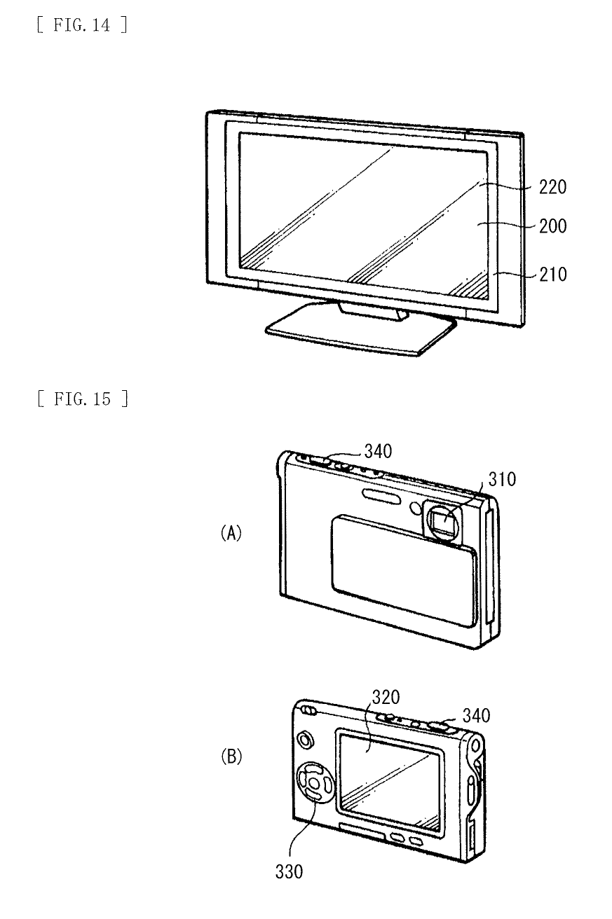

FIG. 14 illustrates an appearance configuration of a television apparatus. The television apparatus may include, for example, a video display screen section 200 (the display unit 1) that includes a front panel 210 and a filter glass 220.

FIG. 15 illustrates an appearance configuration of a digital still camera. Part (A) illustrates a front face thereof, and Part (B) illustrates a rear face thereof. The digital still camera may include, for example, a light emission section 310 for a flash, a display section 320 (the display unit 1), a menu switch 330, and a shutter button 340.

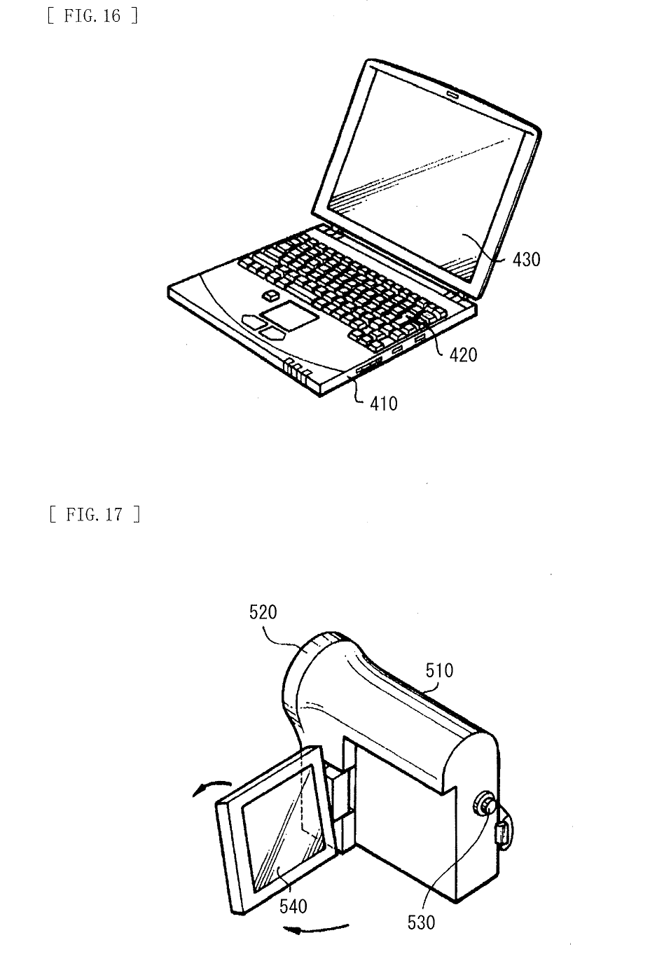

FIG. 16 illustrates an appearance configuration of a notebook personal computer. The personal computer may include, for example, a main body 410, a keyboard 420 for operation of inputting letters etc., and a display section 430 (the display unit 1) that displays an image.

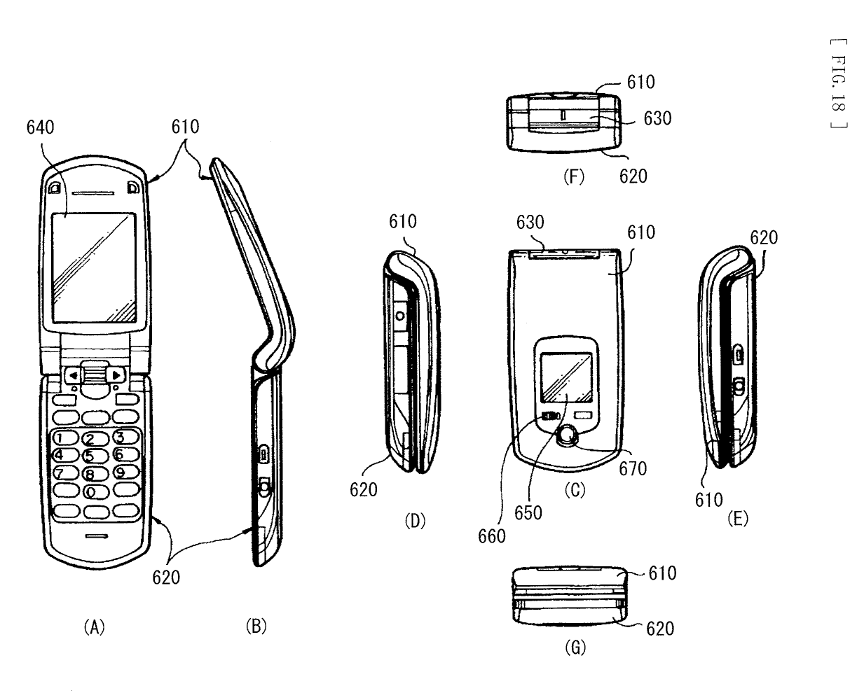

FIG. 17 illustrates an appearance configuration of a video camcorder. The video camcorder may include, for example, a main body section 510, a lens 520, for shooting a subject, that is provided on a forward side surface of the main body section 510, a start-stop switch 530 for shooting, and a display section 540 (the display unit 1).

FIG. 18 illustrates an appearance configuration of a mobile phone. Parts (A) and (B) illustrate a front face and a side face, respectively, of the mobile phone in an open state. Parts (C) to (G) illustrate a front face, a left side face, a right side face, a top face, and a bottom face, respectively, of the mobile phone in a closed state. The mobile phone may be configured, for example, of an upper housing 610 and a lower housing 620 that are connected by a connection section (a hinge section) 620. The mobile phone may include a display 640 (the display unit 1), a sub-display 650, a picture light 660, and a camera 670.

### 4. Examples

Next, Examples of the present technology are described.

### Example 1

First, using the display unit 1 illustrated in FIG. 1 as a model, the dividing walls 12 were formed, on a substrate, so as to have pitches of 17 μm, 21 μm, 30 μm, and 60 μm. It is to be noted that the substrate is a substrate to be printed (a surface to be printed), and may be made of any material as long as the material is capable of supporting glass, plastic, etc. Moreover, the dividing walls 12 were formed to have heights of 0 μm, 0.4 μm, 0.5 μm, 0.7 μm, 0.8 μm, 1.0 μm, 1.2 μm, 1.5 μm, and 2.0 μm. The height of each of the dividing walls 12 is the difference (I) between the dividing wall 12 and the surface to be printed (for example, the first electrode 11) in the above-described embodiment. Subsequently, reverse printing with the use of a blanket was performed on regions partitioned by the dividing walls 12. Presence or absence of transfer defect was examined, and results thereof were shown in Table 1. Here, in the blanket, a PET base or a glass base (each having a thickness from 100 μm to 750 μm) was used as a support substrate, and silicon rubber was used for the formation surface of the printing pattern. It is to be noted that the surface energy of the silicon rubber is 20 mN/m or less. Resolutions of the respective pitches are 500 ppi, 400 ppi, 300 Ippi, and 150 ppi.

TABLE 1

| | Presence or absence of substrate transfer defect | | | | | | | |
|---|---|---|---|---|---|---|---|---|
| | Pitch of | | Pitch of | | Pitch of | | Pitch of | |
| | about 60 μm | | about 30 μm | | about 21 μm | | about 17 μm | |
| | (150 ppi) | | (300 ppi) | | (400 ppi) | | (500 ppi) | |
| h1-h2 | PET | Glass | PET | Glass | PET | Glass | PET | Glass |
| (μm) | base | base | base | base | base | base | base | base |
| 0 | ∘ | ∘ | ∘ | ∘ | ∘ | ∘ | ∘ | ∘ |
| 0.4 | ∘ | ∘ | ∘ | ∘ | ∘ | ∘ | ∘ | ∘ |
| 0.5 | ∘ | ∘ | ∘ | ∘ | ∘ | ∘ | ∘ | ∘ |
| 0.7 | ∘ | ∘ | ∘ | ∘ | ∘ | ∘ | ∘ | ∘ |
| 0.8 | ∘ | ∘ | ∘ | ∘ | ∘ | ∘ | ∘ | ∘ |
| 1.0 | ∘ | ∘ | ∘ | ∘ | ∘ | ∘ | ∘ | ∘ |
| 1.2 | Δ | Δ | Δ | Δ | Δ | x | x | x |
| 1.5 | x | x | x | x | x | x | x | x |
| 2.0 | x | x | x | x | x | x | x | x |

As can be seen from Table 1, in a range of the pitch from 21 μm to 60 μm both inclusive, a transfer defect occurred when the level difference (h) was 1.5 or larger, and a defect portion was observed in part of the printing pattern when the level difference (h) was 1.2 μm. Further, in a case where the pitch was 17 μm, a complete transfer defect occurred when the level difference (h) was 1.2 μm. As described above, it was found that proper transfer of the printing pattern is possible by causing the difference between the height (h1) of the side wall and the height (h2) of the surface to be printed to be 1.0 μm or smaller where the pitch is from 17 μm to 60 μm both inclusive. It is to be noted that the thickness of the support base of the silicon blanket is not particularly limited. Here, the PET base and the glass base having the thickness from 100 μm to 750 μm were used. However, this is not limitative. For example, the thickness thereof may be from 50 μm to 1 mm both inclusive. Moreover, also the thickness of the silicon rubber is not particularly limited, but may be, for example, from 10 μm to 1 mm both inclusive.

The present disclosure is described above referring to the embodiment and the modification. However, the present disclosure is not limited to the above-described embodiment and the like, and various modifications may be made. For example, in the above-described embodiment and the like, the red light emitting layer is formed first as the first light emitting layer formed by a reverse printing method, and then the green light emitting layer is formed as the second light emitting layer formed by a reverse printing method. However, the formation steps of the light emitting layers of the respective colors may be opposite.

Moreover, as the charge transfer material in the present disclosure, an appropriate hole transfer material or an appropriate electron transfer material may be selected depending on the order of formation of the light emitting layers, device characteristics in the respective pixels, etc.

Moreover, in the above-described embodiment, the blanket and the substrate to be printed (the drive substrate 10) are each described with a parallel flat plate as an example (a parallel flat plate—a parallel flat plate). However, this is not limitative. One of the blanket and the substrate to be printed may have a roll shape (a roll—a parallel flat plate, a parallel flat plate—a roll), or both of them may have a roll shape (a roll—a roll). Moreover, the shape of the pixels partitioned by the dividing walls 12 is not particularly limited, and may be, for example, a square having four sides of the same length, or may be a rectangular. Further, the pressing direction of the blanket at the time of printing is not particularly limited, and may be a major-axis direction or a minor-axis direction of the respective pixels.

Moreover, the material and the thickness or the deposition method and the deposition condition, etc. of each of the layers described in the above embodiment and the like are not limitative, and other material and thickness may be used, or other deposition method and deposition condition may be used. Moreover, it is not necessary to provide all of the respective layers described in the above embodiment and the like, and some may be omitted where appropriate. Further, a layer other than the layers described in the above embodiment and the like may be additionally provided. For example, one or a plurality of layers that each use a material having a hole transfer performance as with a common hole transfer layer described in Japanese Unexamined Patent Application Publication No. 2011-233855 may be additionally provided between the charge transfer layer 17 and the blue light emitting layer 14B in the blue EL device 2B. By additionally providing such a layer, light emission efficiency and life characteristics of the blue organic EL device 2B are improved.

It is to be noted that the present technology may also achieve the following configurations.

(1) An organic electroluminescence unit including:

a plurality of light emitting devices arranged having a pitch from 10 micrometers to 60 micrometers both inclusive, and each including a first electrode, an organic layer, and a second electrode that are laminated in order from a substrate, the organic layer including at least a light emitting layer, and at least one layer in the organic layer being formed by a plate printing method; and
a dividing wall provided between adjacent light emitting devices of the plurality of light emitting devices, wherein
a difference between a height, from the substrate, of the dividing wall and a height, from the substrate, of a surface to be printed by the plate printing method is from 0 micrometer to 1 micrometer both inclusive.
   (2) The organic electroluminescence unit according to (1), wherein an angle formed between a side surface of the dividing wall and the first electrode is 90 degrees.
   (3) The organic electroluminescence unit according to (1) or (2), wherein an angle formed between a side surface of the dividing wall and the first electrode is smaller than 90 degrees.
   (4) The organic electroluminescence unit according to (3), wherein the angle formed between the side surface of the dividing wall and the first electrode is 20 degrees or larger.
   (5) The organic electroluminescence unit according to any one of (1) to (4), wherein the height of the dividing wall is larger than that of the first electrode.
   (6) The organic electroluminescence unit according to any one of (1) to (5), wherein a peripheral portion of the first electrode is covered with the dividing wall.
   (7) The organic electroluminescence unit according to any one of (1) to (6), further including:
a red pixel;
a green pixel; and
a blue pixel, wherein
a red light emitting layer is formed in the red pixel, a green light emitting layer is formed in the green pixel, and a blue light emitting layer is formed in the blue pixel.
   (8) The organic electroluminescence unit according to (7), wherein the blue pixel is formed to extend to a region above the red light emitting layer and a region above the green light emitting layer.
   (9) The organic electroluminescence unit according to any one of (1) to (8), further including:
a red pixel;
a green pixel; and
a blue pixel, wherein
a yellow light emitting layer is provided in the red pixel and the green pixel, and
a blue light emitting layer is provided in the blue pixel.
   (10) The organic electroluminescence unit according to any one of (1) to (9), wherein the organic layer includes at least one layer of a hole injection layer, a hole transfer layer, an electron injection layer, and an electron transfer layer, other than the light emitting layer.
   (11) A method of manufacturing an organic electroluminescence unit, the method including:
forming a plurality of first electrodes having a pitch from 10 micrometers to 60 micrometers both inclusive;
forming a dividing wall between the plurality of first electrodes; forming at least one layer, in an organic layer, on the plurality of first electrodes by a plate printing method, the organic layer including at least a light emitting layer; and
forming a second electrode on the organic layer, wherein
causing a difference between a height of the dividing wall and a height of a surface to be printed by the plate printing method to be from 0 micrometer to 1 micrometer both inclusive.
   (12) The method according to (11), wherein
after forming the red light emitting layer and a green light emitting layer,
a blue light emitting layer is formed from a region above the red light emitting layer and a region above the green light emitting layer to a blue pixel region.
   (13) The method according to (11) or (12), wherein a yellow light emitting layer serving as a first light emitting layer is formed in a red pixel region and a green pixel region, and a blue light emitting layer serving as a second light emitting layer is formed in a blue pixel region.
   (14) The method according to any one of (11) to (13), wherein the light emitting layer is formed by the plate printing method.
   (15) The method according to any one of (11) to (14), wherein the light emitting layer is formed by a reverse offset printing method.
   (16) An electronic apparatus including
an organic electroluminescence unit including
a plurality of light emitting devices arranged having a pitch from 10 micrometers to 60 micrometers both inclusive, and each including a first electrode, an organic layer, and a second electrode that are laminated in order from a substrate, the organic layer including at least a light emitting layer, and at least one layer in the organic layer being formed by a plate printing method, and
a dividing wall provided between adjacent light emitting devices of the plurality of light emitting devices, wherein
a difference between a height, from the substrate, of the dividing wall and a height, from the substrate, of a surface to be printed by the plate printing method is from 0 micrometer to 1 micrometer both inclusive.

This application claims priority on the basis of Japanese Patent Application JP 2012-126420 filed Jun. 1, 2012 in Japanese Patent Office, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An organic electroluminescence unit comprising:
a plurality of light emitting devices arranged having a pitch from 10 micrometers to 60 micrometers both inclusive, and each including a first electrode, an organic layer, and a second electrode that are laminated in order from a substrate, the organic layer including at least a light emitting layer, and at least one layer in the organic layer being formed by a plate printing method; and
a dividing wall provided between adjacent light emitting devices of the plurality of light emitting devices, wherein
a difference between a height, from the substrate, of the dividing wall and a height, from the substrate, of a surface to be printed by the plate printing method is from 0 micrometer to 1 micrometer both inclusive.

2. The organic electroluminescence unit according to claim 1, wherein an angle formed between a side surface of the dividing wall and the first electrode is 90 degrees.

3. The organic electroluminescence unit according to claim 1, wherein an angle formed between a side surface of the dividing wall and the first electrode is smaller than 90 degrees.

4. The organic electroluminescence unit according to claim 3, wherein the angle formed between the side surface of the dividing wall and the first electrode is 20 degrees or larger.

5. The organic electroluminescence unit according to claim 1, wherein the height of the dividing wall is larger than that of the first electrode.

6. The organic electroluminescence unit according to claim 1, wherein a peripheral portion of the first electrode is covered with the dividing wall.

7. The organic electroluminescence unit according to claim 1, further comprising:
a red pixel;
a green pixel; and
a blue pixel, wherein
a red light emitting layer is formed in the red pixel, a green light emitting layer is formed in the green pixel, and a blue light emitting layer is formed in the blue pixel.

8. The organic electroluminescence unit according to claim 7, wherein the blue pixel is formed to extend to a region above the red light emitting layer and a region above the green light emitting layer.

9. The organic electroluminescence unit according to claim 1, further comprising:
a red pixel;
a green pixel; and
a blue pixel, wherein
a yellow light emitting layer is provided in the red pixel and the green pixel, and
a blue light emitting layer is provided in the blue pixel.

10. The organic electroluminescence unit according to claim 1, wherein the organic layer includes at least one layer of a hole injection layer, a hole transfer layer, an electron injection layer, and an electron transfer layer, other than the light emitting layer.

11. A method of manufacturing an organic electroluminescence unit, the method comprising:
forming a plurality of first electrodes having a pitch from 10 micrometers to 60 micrometers both inclusive;
forming a dividing wall between the plurality of first electrodes;
forming at least one layer, in an organic layer, on the plurality of first electrodes by a plate printing method, the organic layer including at least a light emitting layer; and
forming a second electrode on the organic layer, wherein
causing a difference between a height of the dividing wall and a height of a surface to be printed by the plate printing method to be from 0 micrometer to 1 micrometer both inclusive.

12. The method according to claim 11, wherein
after forming the red light emitting layer and a green light emitting layer,
a blue light emitting layer is formed from a region above the red light emitting layer and a region above the green light emitting layer to a blue pixel region.

13. The method according to claim 11, wherein a yellow light emitting layer serving as a first light emitting layer is formed in a red pixel region and a green pixel region, and a blue light emitting layer serving as a second light emitting layer is formed in a blue pixel region.

14. The method according to claim 11, wherein the light emitting layer is formed by the plate printing method.

15. The method according to claim 11, wherein the light emitting layer is formed by a reverse offset printing method.

16. An electronic apparatus comprising
an organic electroluminescence unit including
a plurality of light emitting devices arranged having a pitch from 10 micrometers to 60 micrometers both inclusive, and each including a first electrode, an organic layer, and a second electrode that are laminated in order from a substrate, the organic layer including at least a light emitting layer, and at least one layer in the organic layer being formed by a plate printing method, and
a dividing wall provided between adjacent light emitting devices of the plurality of light emitting devices, wherein
a difference between a height, from the substrate, of the dividing wall and a height, from the substrate, of a surface to be printed by the plate printing method is from 0 micrometer to 1 micrometer both inclusive.
